(19) United States
(12) Patent Application Publication
(10) Pub. No.: US 2025/0279336 A1
(43) Pub. Date: Sep. 4, 2025

(54) MICROELECTRONIC DEVICE PACKAGE WITH MULTILAYER PACKAGE SUBSTRATE

(71) Applicant: Texas Instruments Incorporated, Dallas, TX (US)

(72) Inventors: YOU WEI CHANG, Zhubei City (TW); FUKANG LEE, New Taipei City (TW); PI-CHIANG HUANG, Taipei City (TW); GUANGXU LI, Allen, TX (US)

(21) Appl. No.: 18/591,186

(22) Filed: Feb. 29, 2024

(51) Int. Cl. H01L 23/495; H01L 23/00; H01L 25/065

(52) U.S. Cl. CPC H01L 23/49506; H01L 23/4951; H01L 23/49527; H01L 24/08; H01L 24/16; H01L 24/97; H01L 25/0652; H01L 2224/08146; H01L 2224/08155; H01L 2224/16146; H01L 2224/16155; H01L 2224/97; H01L 2924/01029; H01L 2924/014; H01L 2924/15787; H01L 2924/182

(57) ABSTRACT

An example microelectronic device package includes: a leadframe having leads extending from an exterior portion to an interior portion and having lead pads at an end of the interior portion, the lead pads having a first thickness that is less than the a second thickness of the leads; a multilayer package substrate including conductors spaced from one another by dielectric material, a board side surface of the multilayer package substrate mounted to the leadframe by solder joints on the lead pads; at least two semiconductor dies mounted to a device side surface of the multilayer package substrate opposite the board side surface; mold compound covering the multilayer package substrate, the at least two semiconductor dies, the lead pads, and the interior portions of the leads, the exterior portions of the leads free from the mold compound; and the exterior portions of the leads forming terminals for the microelectronic device package.

### TECHNICAL FIELD

This disclosure relates generally to microelectronic device packages, and more particularly to microelectronic device packages including one or more semiconductor dies on a multilayer package substrate mounted within the microelectronic device package.

### BACKGROUND

In packaging semiconductor dies to form packaged devices, multiple semiconductor dies can be mounted to a package substrate. The package substrate can be a multilayer package substrate mounted to leads, for example by being flip chip mounted to lead pads connected to the interior ends of inner leads of a leadframe. The multilayer package substrate can include layers of conductors in dielectric material that may be connected vertically through the dielectric material to form routing paths to connect the semiconductor dies to one another or to other components or terminals in the microelectronic device package. Additional components such as passive devices, including coils, transformers, capacitors, inductors, resistors or sensors can be mounted to or formed within the multilayer package substrate. The leads of the leadframe extend from the interior of the microelectronic device package through an exterior surface of a package body, which can be formed of electronic mold compound (“EMC”). The exterior portions of the leads are then shaped to form external terminals for the microelectronic device package.

One example microelectronic device package is a small outline integrated circuit (“SOIC”) package which has leads extending from a package body on two sides, the leads can be shaped to form terminals including feet portions for use in surface mounting the microelectronic device package to a board or module. The SOIC microelectronic device package can be mounted using solder in a surface mount technology (“SMT”) process. In some example SOIC packages, the exterior portions of the leads have a “gull wing” shape when viewed from a side view and the leads can move slightly during and after board assembly, providing increased board level reliability (“BLR”) by allowing some movement of the leads to reduce thermal stress or to otherwise reduce mechanical stress on the solder joints mounting the microelectronic device package to the board.

Assembly of a microelectronic device package with one or more semiconductor dies on a package substrate that is mounted to leads of a leadframe is done by forming solder joints to mount the package substrate to inner portions of the leads of the leadframe, mounting the semiconductor dies to the package substrate, and subsequently forming a package body using molding to form mold compound around the elements. The individual microelectronic device packages are then separated by cutting through the mold compound between devices, and by cutting through the excess portion of the leadframes that join the individual devices for processing. The leads are then shaped and formed to complete the microelectronic device packages. Delamination can occur between the leads of the leadframe and the mold compound, particularly at the boundary of the mold compound where the leads extend through the mold compound to form the exterior terminals for the device. During certain processes, such as singulation, trim and form (“STF”) processes, the leads may move at the mold compound interface and cause cracking or delamination between the lead surfaces and the mold compound. If delamination occurs, crack propagation can extend a crack defect from the exterior boundary or otherwise into the interior of the microelectronic device package. The crack defect can cause mechanical stress on the internal solder joints between the lead pads and the package substrate mounted on the lead pads, causing failures during testing or in the field, resulting in scrapped devices.

Methods for forming microelectronic device packages including efficient and cost-effective assembly methods and resulting in robust and reliable microelectronic device packages including an integral package substrate are desirable.

### SUMMARY

A described method includes: forming a multilayer package substrate comprising conductors arranged as trace conductor layers spaced from one another by dielectric material and arranged as connection conductor layers coupling portions of the trace conductor layers through the dielectric material, the multilayer package substrate having a device side surface and a board side surface; forming a leadframe having leads extending from an exterior portion to an interior portion and having lead pads at an end of the interior portion for mounting the multilayer package substrate, the lead pads having a first thickness that is less than the a second thickness of the leads; mounting the board side surface of the multilayer package substrate lead pads of the leadframe using solder or a conductive die attach epoxy; mounting at least one semiconductor die to the device side surface of the multilayer package substrate; covering the multilayer package substrate, the at least one semiconductor die, the lead pads, and the interior portions of the leads with mold compound, the exterior portion of the leads free from the mold compound; and forming the exterior portions of the leads to form terminals for a microelectronic device package.

Another described method for forming a microelectronic device package includes: forming a multilayer build-up package substrate including conductors arranged as trace conductor layers spaced from one another by dielectric material and arranged as connection conductor layers coupling portions of the trace conductor layers through the dielectric material, the dielectric material being Ajinomoto build-up film (ABF), the multilayer package substrate having a device side surface and a board side surface; using a partial etch process, forming a leadframe having leads extending from an exterior portion to an interior portion and having lead pads at an end of the interior portion for mounting the multilayer package substrate, the lead pads having a first thickness that is less than a second thickness of the leads, the second thickness being the full thickness of the leadframe; mounting the board side surface of the multilayer package substrate lead pads of the leadframe using solder; mounting at least two semiconductor dies to the device side surface of the multilayer package substrate; covering the multilayer build-up package substrate, the at least two semiconductor dies, the lead pads, and the interior portions of the leads with mold compound, the exterior portion of the leads free from the mold compound; and trimming and forming the exterior portions of the leads to separate the exterior portions of the leads and form terminals for a microelectronic device package.

In a described example, a microelectronic device package includes: a leadframe having leads extending from an exterior portion to an interior portion and having lead pads at an end of the interior portion, the lead pads having a first thickness that is less than a second thickness of the leads; a multilayer package substrate including conductors arranged as trace conductor layers spaced from one another by dielectric material and arranged as connection conductor layers coupling portions of the trace conductor layers through the dielectric material, the multilayer package substrate having a device side surface and a board side surface, the board side surface of the multilayer package substrate mounted to the leadframe by solder joints on the lead pads; at least two semiconductor dies mounted to the device side surface of the multilayer package substrate; mold compound covering the multilayer package substrate, the at least two semiconductor dies, the lead pads, and the interior portions of the leads, the exterior portions of the leads free from the mold compound; and the exterior portions of the leads forming terminals for the microelectronic device package.

### BRIEF DESCRIPTION OF THE DRAWINGS

FIGS. 1A-1B illustrate, in a projection view and a close-up projection view, respectively, semiconductor dies on a semiconductor wafer and an individual semiconductor die from the semiconductor wafer, for use with the arrangements.

FIG. 2 illustrates, in a projection view, an example small outline integrated circuit (“SOIC”) package that can be used with the arrangements.

FIG. 3A illustrates, in a cross-sectional view, an SOIC package that can be used with the arrangements. FIG. 3B illustrates, in a plan view, an example unit leadframe with a package substrate that can be used with an arrangement in a microelectronic device package.

FIGS. 4A-4B illustrate, in a series of cross-sectional views, the major steps in manufacturing an example multilayer build-up package substrate that can be used in the arrangements.

FIG. 5A illustrates, in a projection view, a sub-assembly for an arrangement including a multilayer package substrate mounted to a unit leadframe using flip chip assembly. FIGS. 5B-5C illustrate the sub-assembly of FIG. 5A in a plan view from a top side, and in an end view, respectively, to further show additional details. FIGS. 5D-5DD illustrate, in a projection view and a side view, respectively, a single lead showing details of the lead pad and a lead that are useful in the arrangements, including in the sub-assembly of FIGS. 5A-5C. FIGS. 5E-5EE illustrate, in another projection view and another side view, respectively, an alternative form for a single lead showing details of the lead pad and a lead that are useful in the arrangements.

FIGS. 6A-6G illustrate, in a series of cross-sectional views, selected steps for forming a microelectronic device package of an arrangement.

FIGS. 7A-7C illustrate, in another series of cross-sectional views, selected steps for forming an alternative arrangement for a microelectronic device package.

FIG. 8 illustrates, in a close-up cross-sectional view, an example crack propagation event for a microelectronic device package incorporating an arrangement.

FIG. 9 illustrates, in a flow diagram, steps for forming a microelectronic device package incorporating an arrangement.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device” is used herein. A semiconductor device can be a discrete semiconductor device such as a bipolar transistor, a few discrete devices such as a pair of power field effect transistor (“FET”) switches fabricated together on a single semiconductor die, or a semiconductor device can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device can be a radio transceiver or a radar transceiver. The semiconductor device can be a receiver, transmitter or transceiver. When semiconductor devices are fabricated on a semiconductor wafer and then individually separated from the semiconductor wafer, the individual units are referred to as “semiconductor dies.” A semiconductor die is also a semiconductor device.

The term “microelectronic device package” is used herein. A microelectronic device package is a package that has at least one semiconductor die electrically coupled to leads that form terminals, and has a package body that protects and covers the semiconductor die. The microelectronic device package can include additional elements, in some arrangements an integrated coil or transformer can be included. Passive components such as capacitors, resistors, and inductors or coils can be included. In some arrangements, multiple semiconductor dies can be packaged together. In example arrangements, the semiconductor die(s) is/are mounted to a multilayer package substrate. In the arrangements, the multilayer package substrate is flip chip mounted to lead pads of a leadframe that provides conductive leads. Exterior portions (external to the package body) of the conductive leads form the terminals for the microelectronic device package. In one approach the semiconductor dies can be mounted to the multilayer package substrate in a flip chip configuration, with a device side surface of the semiconductor dies facing the multilayer package substrate and the backside surface of the semiconductor dies facing away from the multilayer package substrate. In example arrangements the semiconductor dies can be mounted on a device side surface of the multilayer package substrate that is opposite a board side surface of the microelectronic device package, while passive components can be mounted on either the device side or the board side surface of the multilayer package substrate. In some examples, passive components can be formed of conductors within the multilayer package substrate, such as coils or inductors. Conductive pads on the board side surface of the multilayer package substrate are coupled to lead pads at the interior ends of leads of the leadframe by solder balls, the solder balls are subsequently melted in a reflow process to form solder joints. The microelectronic device package can have a package body formed by a mold compound of thermoset epoxy resin in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the leadframe are not covered during encapsulation, these exposed exterior lead portions form the terminals for the microelectronic device package.

The term “package substrate” is used herein. A package substrate is a substrate arranged to receive a semiconductor die and to support the semiconductor die in a completed microelectronic device package. Package substrates useful with the arrangements include conductive leadframes, molded interconnect substrates (MIS), partially etched leadframes, pre-molded leadframes (PMLFs), and multilayer package substrates. In some arrangements, flip chip die mounting is used, where post connects that extend from bond pads on the semiconductor dies are attached by a solder joint to conductive lands on the device side surface of a multilayer package substrate. The post connects can be solder bumps or other conductive materials such as copper or gold extending from the bond pads with solder on a distal end. Copper pillar bumps can be used. In alternative arrangements using wire bonding, bond wires can couple bond pads on the semiconductor dies to conductive traces or lands on the device side surface of the multilayer package substrate.

The term “multilayer build-up package substrate” is used herein. A multilayer build-up package substrate is a package substrate that has multiple conductor layers including trace conductor layers, and has connection conductor layers extending through the dielectric material between the trace conductor layers. In an example arrangement, a multilayer build-up package substrate is formed in an additive manufacturing process by plating a patterned trace conductor layer and then covering the trace conductor layer, and in some examples a connection conductor layer is plated over the trace conductor layer, with a layer of dielectric material. The dielectric material can be cured to form a solid layer. Grinding or thinning can be performed on the dielectric material to expose portions of the top surface of the layer of conductors from the dielectric material. Additional plating layers can be formed to add additional levels of trace conductor layers, some of which are trace conductor layers that are coupled to other trace conductor layers in the dielectric materials by connection conductor layers extending through the dielectric material, and additional dielectric material can be deposited at each trace conductor layer and can cover the conductors. By using an additive or build-up manufacturing approach, and by performing multiple plating steps, multiple dielectric formation steps, and multiple grinding steps, a multilayer build-up package substrate is formed with an arbitrary number of trace conductor layers and connection conductor layers between and coupling portions of the trace conductor layers. In an example process, Ajinomoto build-up film (“ABF”) is used as the dielectric material, and copper conductors and copper connections are plated in an electroless or electroplating process.

In packaging microelectronic and semiconductor devices, mold compound may be used to partially cover a package substrate, to cover components, to cover a semiconductor die, and to cover the electrical connections from the semiconductor die to the package substrate. This molding process can be referred to as an “encapsulation” process, although some portions of the package substrates are not covered in the mold compound during encapsulation, for example terminals and leads are exposed from the mold compound to enable electrical connections to the packaged device. Encapsulation is often a compressive molding process, where a thermoset mold compound such as epoxy resin can be used. A room temperature solid or powdered mold compound can be heated to a liquid state in the mold tool, and then molding can be performed by pressing the liquid mold compound into a mold through runners or channels. Transfer molding can be used. Unit molds shaped to surround an individual device may be used, or block molding may be used, to form multiple packages simultaneously for several devices from mold compound. The devices to be molded can be provided mounted to a leadframe in an array or matrix of several, hundreds or even thousands of devices in rows and columns that are then molded together. The leadframe array is positioned in the mold prior to encapsulation.

After the molding process is complete, the individual microelectronic device packages are cut apart from each other in a sawing operation by cutting through the mold compound and any excess leadframe material in saw streets formed between the molded devices. External portions of the leadframe leads are exposed from the mold compound package to form terminals for the packaged semiconductor device.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between devices, such as molded electronic devices, to allow a saw, such as a mechanical blade, a laser, or other cutting tool to pass between devices to separate the devices from one another. This process is another form of singulation. When the molded electronic devices are provided in a strip with one device adjacent to another device along the strip, the saw streets are both parallel to and normal to the length of the strip. When the molded electronic devices are provided in an array of devices in rows and columns, the saw streets include two groups of parallel saw streets, the two groups are normal to each other, and the saw will traverse the molded electronic devices in two different directions to cut apart the packaged electronic devices from one another in the array.

The terms “interior portion” and “exterior portion” are used herein to describe parts of leads. The leads of a leadframe for a leaded microelectronic device package have portions that will be covered with mold compound and which will be inside the package body, these portions are “interior portions” as the leads are described herein. The leads of a leadframe for a leaded microelectronic device package have portions that extend from and are outside the package body formed by the mold compound, these portions are described herein as “exterior portions” of the leads. In example arrangements, the leads also have a “lead pad” connected to the inner end of the interior portions, and the lead pads have a thickness that is less than the lead thickness. A step is formed where the lead pads meet the interior portion of the leads, this step acts as a crack stop feature, as is described below, increasing the reliability of the microelectronic device packages formed using the arrangements.

In the arrangements, a microelectronic device package includes at least a single semiconductor die mounted on a multilayer package substrate. In the illustrated examples, multiple semiconductor dies are mounted on a device side surface of a multilayer package substrate. The multilayer package substrate is flip chip mounted at a board side surface to lead pads at the end of interior portions of the leads of a leadframe. In the arrangements, the interior portion of the leads of the leadframe have a thickness that is greater than the thickness of the lead pads. For example, the lead pads can have a thickness that is approximately half the thickness of the leads. The leadframe leads can be formed, in an example process, using a partial etch or “half etch” process to produce a leadframe with lead pads and leads having the two different thicknesses. After the multilayer package substrate is mounted to the lead pads by solder joints, and after the semiconductor dies are then mounted to the multilayer package substrate, mold compound encapsulates the devices to form the microelectronic device package. By use of the arrangements, a crack stop feature is formed between the lead and the lead pads, so that in the event a delamination crack occurs between the leads and the mold compound, and the crack begins propagating into the mold compound of the package, the change in thickness creates a step forming a barrier that prevents the crack from reaching the solder joint, increasing reliability of the microelectronic device package, and decreasing the likelihood a completed device will be scrapped or fail in testing or in in use.

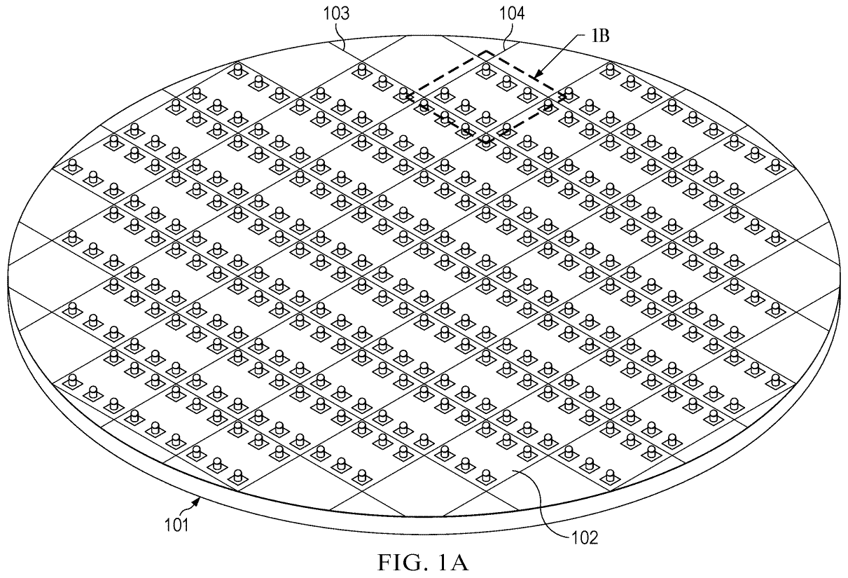

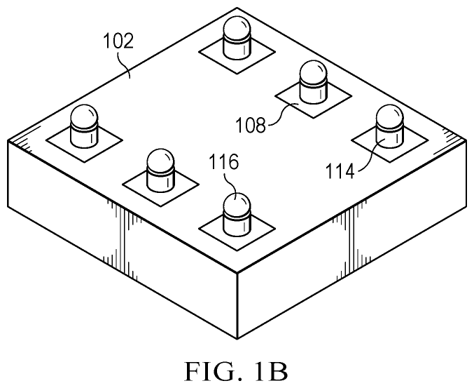

FIGS. 1A and 1B illustrate, in two projection views, a semiconductor wafer having semiconductor die devices formed on it and arranged for flip chip mounting, and an individual semiconductor die arranged for flip chip mounting, respectively. In FIG. 1A, a semiconductor wafer 101 is shown with an array of semiconductor dies 102 formed in rows and columns on a device side surface. The semiconductor dies 102 can be formed using processes in a semiconductor manufacturing facility, including ion implantation, doping, anneals, oxidation, dielectric and metal deposition, photolithography, pattern, etch, chemical mechanical polishing (CMP), electroplating, and other processes for making semiconductor devices. Scribe lanes 103 and 104, which are perpendicular to one another, and which run in parallel groups across the wafer 101, separate the rows and columns of the completed semiconductor dies 102, and provide areas for dicing the wafer 101 to separate the semiconductor dies 102 from one another.

FIG. 1B illustrates a single semiconductor die 102 taken from semiconductor wafer 101. Semiconductor die 102 includes bond pads 108, which are conductive pads that are electrically coupled to devices (not shown) that are formed in the semiconductor die 102. Conductive post connects 114 are shown extending away from an end on the bond pads 108 on the surface of semiconductor die 102 to a distal end, and solder bumps 116 are formed on the distal ends of the conductive post connects 114. The conductive post connects 114 can be formed by electroless plating or electroplating. In an example, the conductive post connects 114 are copper, and have solder bumps 116 on the distal ends, and are sometimes referred to as “copper pillar bumps.” In an example process, copper pillar bumps can be formed by sputtering a seed layer over the surface of the semiconductor wafer 101, forming a photoresist layer over the seed layer, using photolithography to expose seed layer over the bond pads 108 in openings in the layer of photoresist, and then plating the copper conductive post connects 114 on the bond pads, and plating a lead solder or a lead-free solder such as an tin, silver (SnAg) or tin, silver, copper (SnAgCu) or “SAC” solder to form solder bumps 116 on the copper conductive post connects 114. In an alternative approach, solder bumps or particles may be dropped onto the distal ends of the conductive post connects 114 (which can be, in an example, copper pillars) and then reflowed in a thermal process to form copper pillar bumps. Other conductive materials can be used for the conductive post connects in an electroplating or electroless plating operation, including gold, silver, nickel, palladium, or tin, for example. Not shown for clarity of illustration are under bump metallization (UBM) portions which can be formed over the bond pads to improve plating and adhesion between the conductive post connects 114 and the bond pads 108. After the plating operations, the photoresist is then stripped, and the excess seed layer is etched from the surface of the wafer. Polyimide (“PI”) (not shown) or other dielectric can be applied between the conductive post connects to protect the semiconductor die 102 and the conductive post connects 114. The semiconductor dies 102 are then separated by dicing, or are singulated, using the scribe lanes 103, 104 (see FIG. 1A).

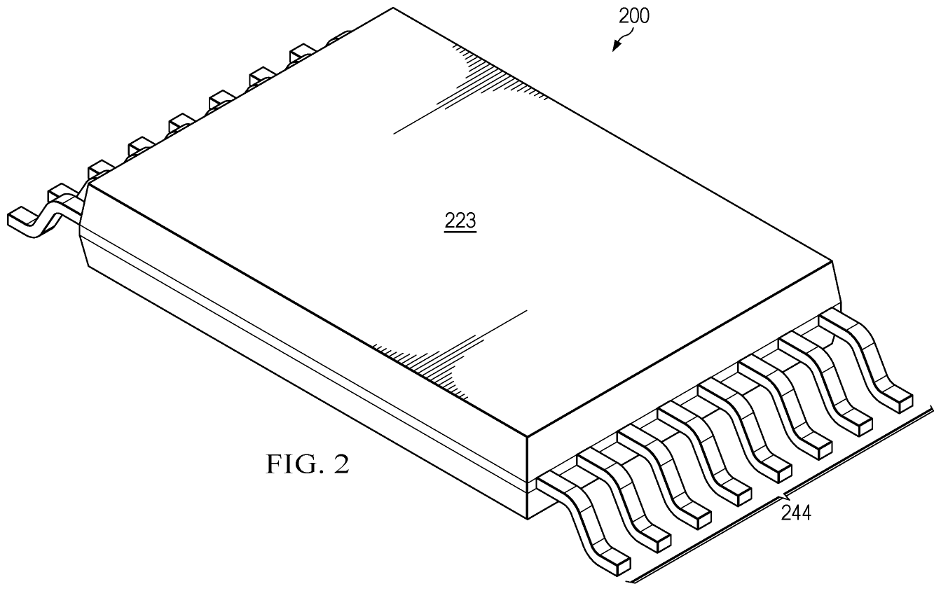

FIG. 2 illustrates, in a projection view from a top side, an example microelectronic device package 200 that can be used with the arrangements. The microelectronic device package 200 shown in FIG. 2 is a small outline integrated circuit (“SOIC”) package with terminals formed by leads 244 extending from two sides of a package body formed of mold compound 223. SOIC packages have excellent board level reliability (“BLR”) in surface mount technology (“SMT”) assembled boards and modules, in part because the leads 244 with the external portions having “gull wing” shapes allow some movement. This allows some movement that can prevent packaged device-to-board solder joint failures during thermal cycling when the microelectronic device package 200 is in use, or during testing. In alternative arrangements, other leaded packages can be used including small outline (“SO”) such as “small outline packages” or “SOP.”

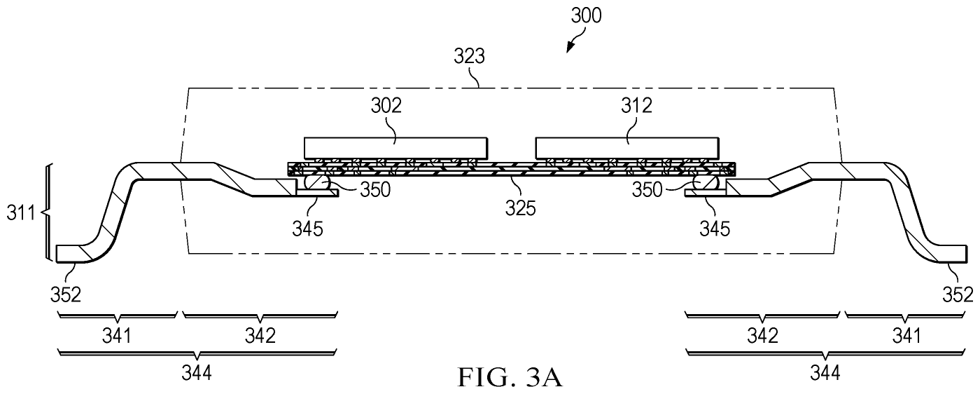

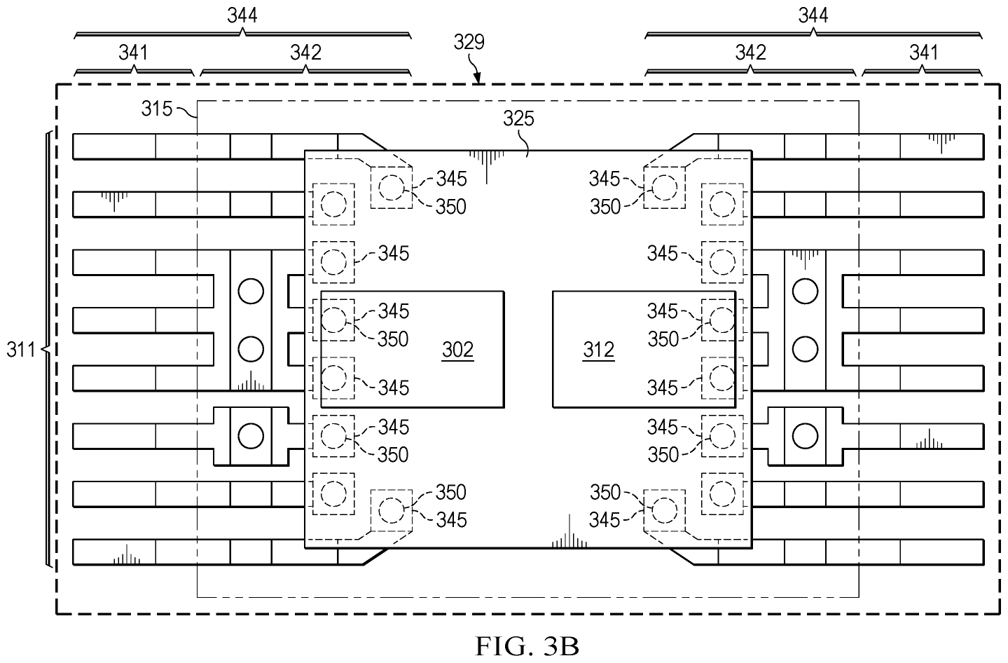

FIG. 3A illustrates in a cross-sectional view a microelectronic device package 300 similar to the microelectronic device package 200 of FIG. 2. The microelectronic device package 300 has a multilayer package substrate 325 that is flip chip mounted to a leadframe 311. The leadframe 311 has leads 344 with exterior portions 341, external to a mold compound 323, that form terminals, and interior lead portions 342 that extend into the mold compound 323. The leads 344 have lead pads 345 on the interior ends of the interior lead portions 342, where the multilayer package substrate 325 is flip chip mounted by solder joints. In one example the solder joints are formed using solder balls in a reflow process. Semiconductor dies 302 and 312 are shown mounted to a device side surface of the multilayer package substrate 325. In the illustrated examples, the semiconductor dies are flip chip mounted to the device side surface of the multilayer package substrate 325. Because the illustrated example microelectronic device package 300 has two semiconductor dies within the package, it can be referred to as a “multi-chip module” or as an “MCM.” Example arrangements can have two or more semiconductor dies as shown herein, however, in another example a single semiconductor die can be mounted to the multilayer package substrate within the microelectronic device package. In an example application for a single semiconductor die, the multilayer package substrate can perform a mapping function to map the bond pads of a semiconductor die to the terminals of the package. This application enables changing dies in a particular package without the need to change the board layouts already in use, for example. In another example application for a single semiconductor die, the multilayer package substrate 325 can have passive components formed within it, or mounted on either side of it, that are then coupled to the semiconductor die by traces within the multilayer package substrate. The leads 344 have feet portions 352 where the microelectronic device package 300 can be mounted on a board or module using solder in an SMT assembly process.

FIG. 3B illustrates, in a plan view, additional details of the leadframe 311 and the multilayer package substrate 325 shown in FIG. 3A, shown from a top view. Semiconductor dies 302 and 312 are shown on the device side surface of the multilayer package substrate 325. The leads 344 of the leadframe 311 have exterior portions 341 that extend across a mold compound boundary 315 to interior lead portions 342. The interior lead portions 342 extend to lead pads 345 on an interior end. The multilayer package substrate 325 is mounted to the lead pads 345 by solder joints 350. Dashed line 329 indicates the plan view of FIG. 3B is a partial view, in a complete microelectronic device package the leads 344 extend beyond the view shown (see leads 344 in FIG. 3A).

In the arrangements, the multilayer package substrate can be a molded interconnect substrate (“MIS”) formed using thermoset epoxy resin mold compound as a dielectric that is formed around conductors. In other examples the multilayer package substrate can be a laminate, a glass fiber reinforced epoxy substrate such as flame-retardant 4 (“FR4”), a bismaleimide-triazine resin (“BT”) substrate, or a multilayer build-up package substrate. Multilayer build-up package substrates can be formed using Ajinomoto build-up film (“ABF”) commercially available from Ajinomoto Co. Inc., of Tokyo, Japan, for example.

While in the illustrated examples, the microelectronic device packages have 8 or 16 terminals, leaded packages that can be used with the arrangements can have more, or fewer, terminals, for example 20 terminals, 32 terminals, less, or more. The leadframe 311 can be of copper, a copper alloy, steel, stainless steel, Alloy 42, and can be plated either completely or spot plated, some pre-plated leadframes can include nickel, gold, palladium, tin, or silver plating to enhance solderability or reduce oxidation or tarnish. Spot plating can be performed to enhance the solder joints at positions on the leads where solder is to be applied.

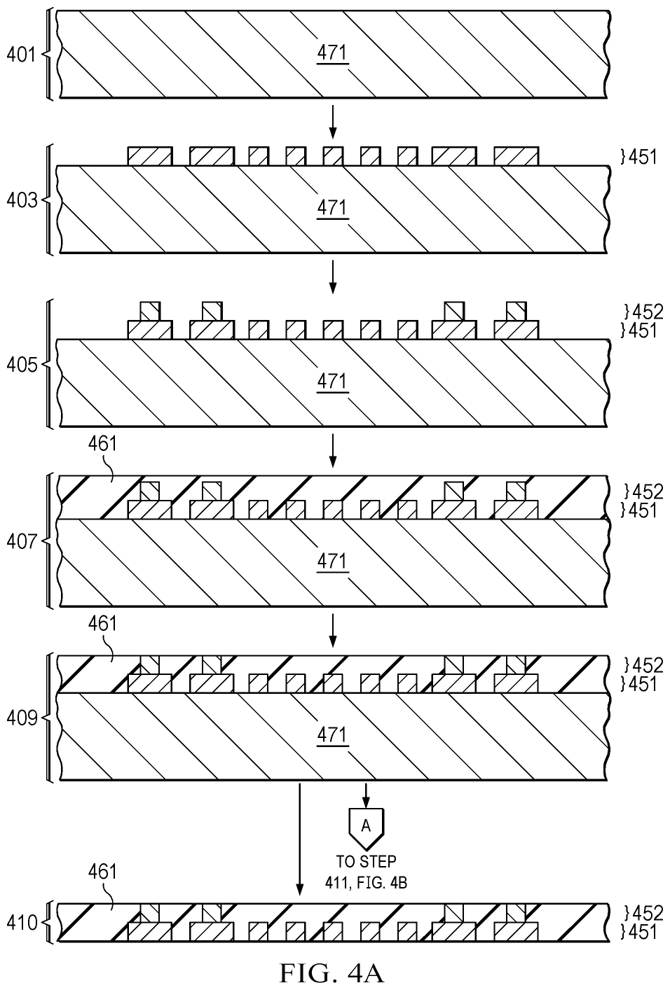

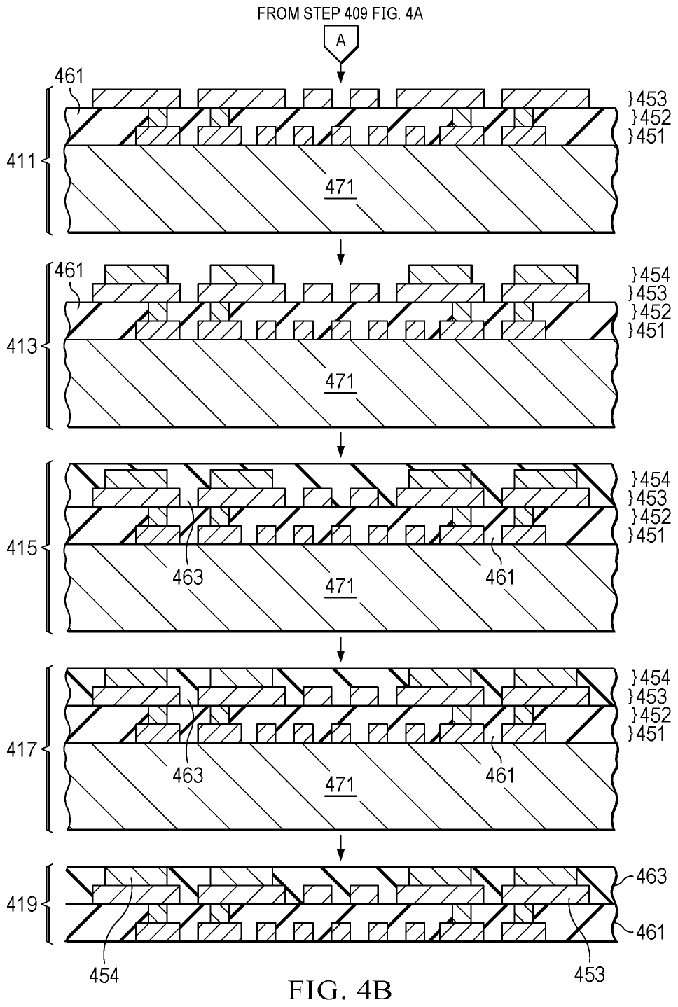

FIGS. 4A-4B illustrate, in a series of cross-sectional views, selected steps of a method for forming a multilayer build-up package substrate that is useful with the arrangements. Note that in FIGS. 4A-4B, two trace conductor layers, and two connection conductor layers, are shown for purposes of explanation; however, in useful examples additional conductor layers can be formed using the additive manufacturing or build-up processes. In addition, in some examples the conductors can be patterned to form components, such as planar coils, that can be coupled to the semiconductor dies or to other components to form circuitry. Capacitors, resistors, inductors and sensors can be formed within the multilayer package substrate or mounted on either side of the multilayer package substrate. The vertical connections are described herein as “connection conductor layers” to distinguish the plated connections from “vias” which are used in laminate substrates. Vias in substrates are typically formed by filling a hole in a solid dielectric with conductor material such as a plug. In contrast, as is further described below, the connection conductor layers in the multilayer build-up substrates are formed using plating processes, the plated conductors are then covered with film that forms the dielectric layer around them.

In FIG. 4A, at step 401, a metal, semiconductor or glass carrier 471 is readied for a plating process. The carrier 471 can be stainless steel, steel, aluminum or another metal, or can be a silicon wafer or a glass that will support the multilayer build-up package substrate layers during plating and molding steps, the multilayer build-up package substrate is then removed, and the carrier 471 can be discarded or can be cleaned for use in additional manufacturing processes.

At step 403, a first trace conductor layer 451 is formed by plating. In an example process, a seed layer is deposited over the surface of carrier 471, by sputtering, chemical vapor deposition (CVD) or other deposition step. A photoresist layer is deposited over the seed layer, exposed, developed and cured to form a pattern to be plated. Electroless or electroplating is performed using the exposed portions of the seed layer to start the plating, forming a pattern according to patterns in the photoresist layer. The conductor layers can be plated of copper, gold, aluminum, silver or an alloy thereof. In a particular example, copper is used.

At step 405, the plating process continues. A second photoresist layer is deposited, exposed, and developed to pattern the first connection conductor layer 452. By leaving the first photoresist layer in place, the second photoresist layer is used without an intervening photoresist strip and clean step, to simplify processing. The first trace conductor layer 451 can also be used as a seed layer for the second plating operation, to further simplify processing, as another seed layer sputter process is not performed at this step. In an alternative process, a second sputter process can be used instead.

At step 407, a first dielectric material is deposited. The first trace conductor layer 451 and the first connection conductor layer 452 are covered in a dielectric material 461. In an example process, a thermosetting resin material is used, in a particular example Ajinomoto build-up film (“ABF”) is used. ABF is commercially available from Ajinomoto Co. Inc., Tokyo, Japan. In alternative examples acrylonitrile butadiene styrene (ABS), acrylonitrile styrene acrylate (ASA), or resin epoxy mold compound can be used; resins, epoxies, or plastics can be used. In an example deposition process using ABF, roll ABF film is used. The ABF film is laminated over the trace conductor layer 451 and the connection conductor layer 453. In an example process, a thermal process relaxes the ABF film at an elevated temperature and using vacuum, the ABF film softens and conforms to the conductor layers to fill the spaces with the ABF film dielectric, without voids. The dielectric material 461 can then be cured to harden the dielectric ABF material for additional processes.

At step 409, a grinding operation is performed on the surface of the dielectric material 461. The grinding operation exposes a surface of the connection conductor layer 452 and provides conductive surfaces for mounting devices, or for use in additional plating operations. If the multilayer build-up package substrate is complete at this step, the method ends at step 410, where a de-carrier operation removes the carrier (see 471 in step 409) from the dielectric material 461, leaving the first trace conductor layer 451 and the first connection conductor layer 452 in dielectric material 461, providing a multilayer build-up package substrate.

In examples where additional trace conductor layers and additional connection conductor layers are needed, the method continues, leaving step 409 and transitioning to step 411 in FIG. 4B. The multilayer build-up package substrate is shown supported on carrier 471 with first trace conductor layer 451 and connection conductor layer 452 in dielectric material 461.

FIG. 4B illustrates an example for forming a multilayer package substrate with additional layers, transitioning from step 409 in FIG. 4A. At step 411, in FIG. 4B, a second trace conductor layer 453 is formed by plating using the same processes as described above with respect to step 405. An additional seed layer for the additional plating operation is deposited and a photoresist layer is deposited and patterned, and the plating operation forms the second trace conductor layer 453 over the dielectric material 461, with portions of the second trace conductor layer 453 electrically connected to the first connection conductor layer 452.

At step 413, a second connection conductor layer 454 is formed using an additional plating step on the second trace conductor layer 453. The second connection conductor layer 454 can be plated using the second trace conductor layer 453 as a seed layer, and without the need for removing the preceding photoresist layer, simplifying the process. Alternatively, additional seed layer deposition can be performed.

At step 415, a second dielectric deposition operation is performed to cover the second trace conductor layer 453 and the second connection conductor layer 454 in a layer of dielectric material 463. The multilayer build-up package substrate at this stage has a first trace conductor layer 451, a first connection conductor layer 452, a second trace conductor layer 453, and a second connection conductor layer 454, portions of the conductors are electrically connected together to form conductive paths through the layers of dielectric material 461 and 463.

At step 417, the layer of dielectric material 463 is mechanically ground in a grinding process or is chemically etched to expose a surface of the second connection conductor layer 454. At step 419 the example method ends by removing the carrier 471 (see step 417), leaving a multilayer build-up package substrate including the trace conductor layers 451 and 453, and connection conductor layers 452 and 454, in the layers of dielectric material 461, 463. The steps of FIGS. 4A-4B can be repeated to form multilayer build-up package substrates for use with the arrangements having more conductor and connection conductor layers, by performing plating of a trace conductor layer, plating of a connection conductor layer, adding a dielectric material covering the conductor layers, and grinding, repeatedly.

Useful sizes for an example of the multilayer build-up package substrate for small outline packages could be from two to seven millimeters wide by two to seven millimeters long, for example. The size of the multilayer build-up package substrate can be varied depending on the size and number of semiconductor dies used, as well as the size and number of passive components, if any are included, and the package type being formed. The area of the device side surface should be sufficient for mounting the semiconductor dies, and for forming passives such as coils or transformers within or on the multilayer build-up package substrate.

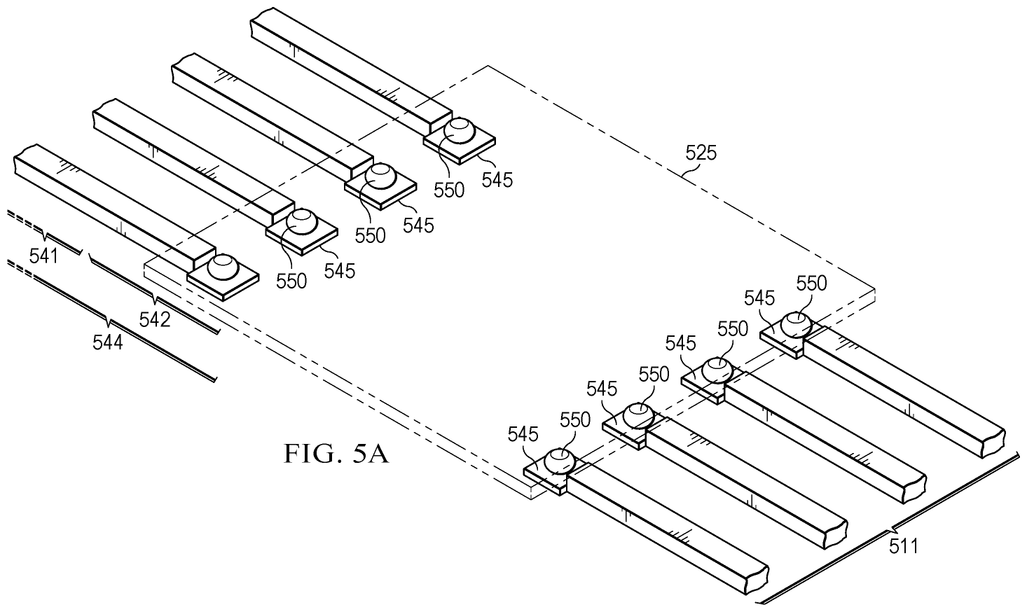

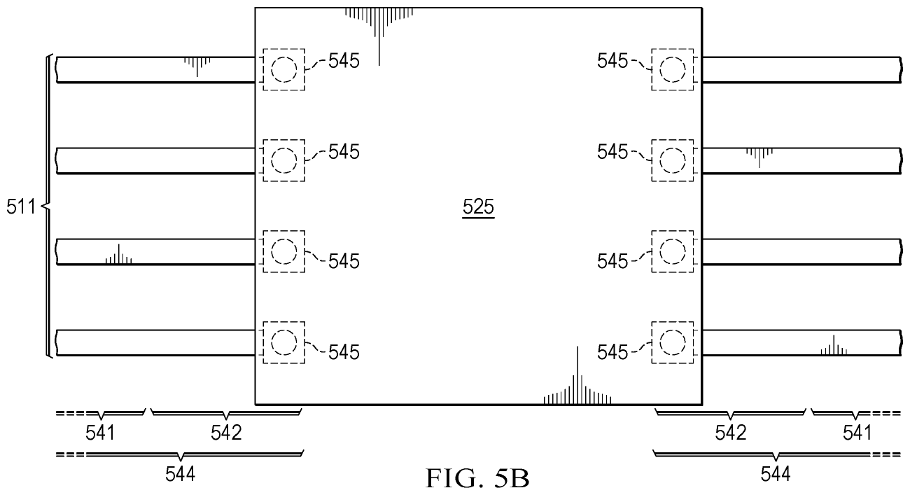

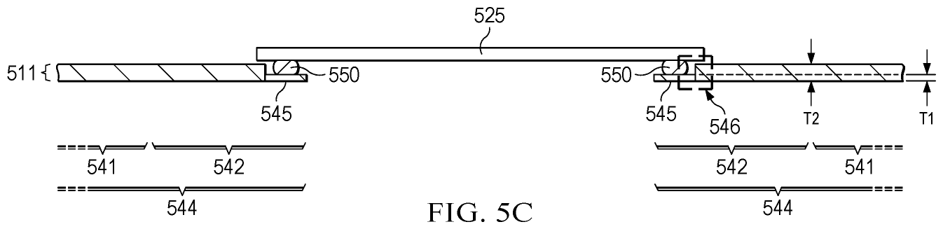

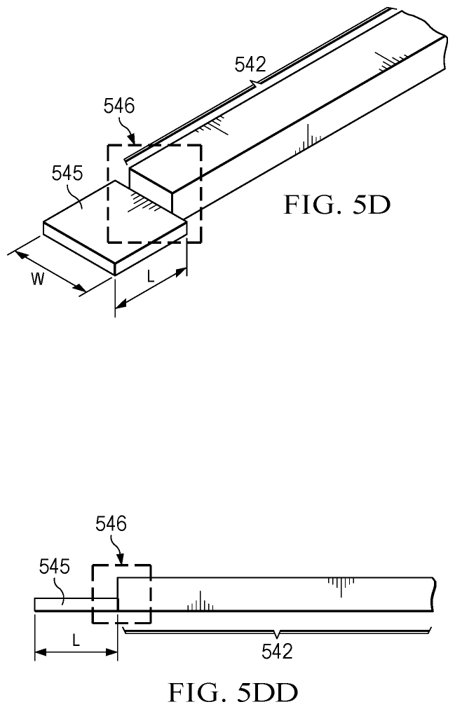

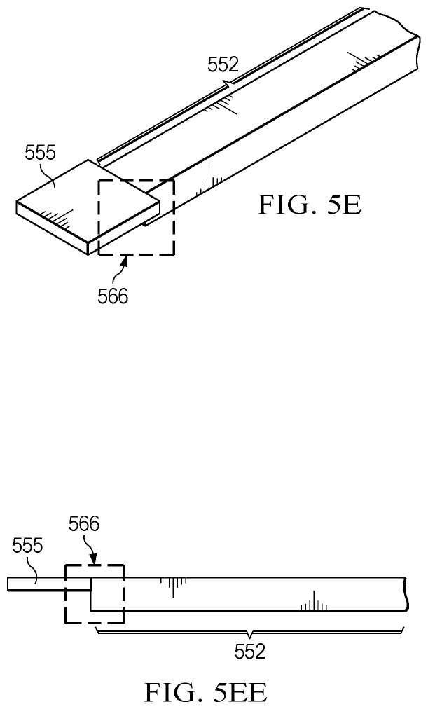

FIGS. 5A-5C illustrate, in a projection view, a plan view, and an end view, respectively, details of a particular example sub-assembly for use in the arrangements. FIGS. 5D-5DD illustrate, in a projection view and a side view, details of an example lead shape used in an arrangement, and FIGS. 5E-5EE illustrate, in another projection view and another side view, details of an alternative lead shape for use in the arrangements.

FIG. 5A illustrates a multilayer package substrate 525 that is flip chip mounted to leads 544 of a leadframe 511. The leads 544 have an interior lead portion 542 (that will be interior to a mold compound body formed in a later step, described below) that extends to lead pads 545 on the interior ends. The lead pads 545 are coupled to the multilayer package substrate 525 by solder joints 550, which are formed by a solder reflow process where solder balls placed between the multilayer package substrate and the lead pads 545 are heated to melt and reflow to form solder joints.

FIG. 5B illustrates, in a plan view from a top side, the elements of FIG. 5A. The multilayer package substrate 525 is shown partially transparent to allow visibility of the lead pads 545 below. Leads 544 have interior portions 542 that extend to the lead pads 545 (the exterior lead portions 541 of leads 544 are not completely shown in FIGS. 5A-5C). In the arrangements, the leads 544 are thicker than the lead pads 545 of the leadframe 511.

In FIG. 5C, an end view of the elements of FIGS. 5A-5B is shown. In FIG. 5C, solder joints 550 that couple the lead pads 545 to the multilayer package substrate are shown. The lead pads 545 have a first thickness (labeled “T1”) that is less than the second thickness (labeled “T2”) of the leads 544, creating a step (shown in dashed area 546) where the interior lead portions 542 meet the lead pads 545.

In an example method for forming an arrangement, the leadframe 511 can be formed in a partial etching process from a sheet of leadframe material. In a partial etch process, which can be a half-etch process (but is not limited to half etching), the leadframe leads 544 and the lead pads 545 are formed by etching a sheet of the leadframe material from both sides. The etches include patterning so that some areas of full thicknesses that are not etched, some areas with openings which are fully etched, and some areas with partially etched thicknesses such as the lead pads 545, can be formed. In an example, the leads 544 may have a thickness (labeled “T2” in FIG. 5C) of about 10 mils (thousands of an inch) or 0.25 millimeters, with the lead pads 545 having a thickness (labeled “T1” in FIG. 5C) of about 5 mils or about 0.12 millimeters. Other thicknesses can be used. In useful examples with a leadframe thickness of about 10 mils, the lead pads 545 can range in thickness from 4-6 mils, and need not be “half etched” but can be partially etched relative to the full thickness of the leadframe 511.

In FIGS. 5D-5DD, an example of an interior portion 542 of a lead with the partially etched lead pad 545 at the end of the interior portion is shown in both a projection view (FIG. 5D) and a side view (FIG. 5DD). The step formed is shown in dashed area 546. In this example arrangement, the lead pad 545 is formed at a board side surface of the lead, with the upper surface of the lead pad 545 (as oriented in FIGS. 5D-5DD) for the solder joint (not shown) being positioned at a level below the level of the top surface of the lead. The lead pad 545 can have length “L” that varies in a range from 400-1000 microns, and a width “W” that can be around 400 microns in the example, but the lead pads 545 can vary in area and are sized and shaped to support and receive the solder joint, and can be wider than the leads.

In FIGS. 5E-5EE, an alternative arrangement of a lead with an interior lead portion 552 and lead pad 555 is shown in both a projection view and a side view. In FIG. 5E, the lead is shown with the lead pad 555 positioned at the device side of the lead, so that the solder joint (not shown) will be formed at a level that matches the level of the top surface of the lead. A step is shown in the dashed area 566 between the lead pad 555 and the interior lead portion 552 of the lead. The alternative arrangement shown in FIGS. 5E-5EEE has the step between the bottom surface of the lead and the lead pad 555, forming a crack reduction feature by disrupting a path along the interior lead portion 552 before a crack can reach the lead pad and impact a solder joint (not shown) on the lead pad.

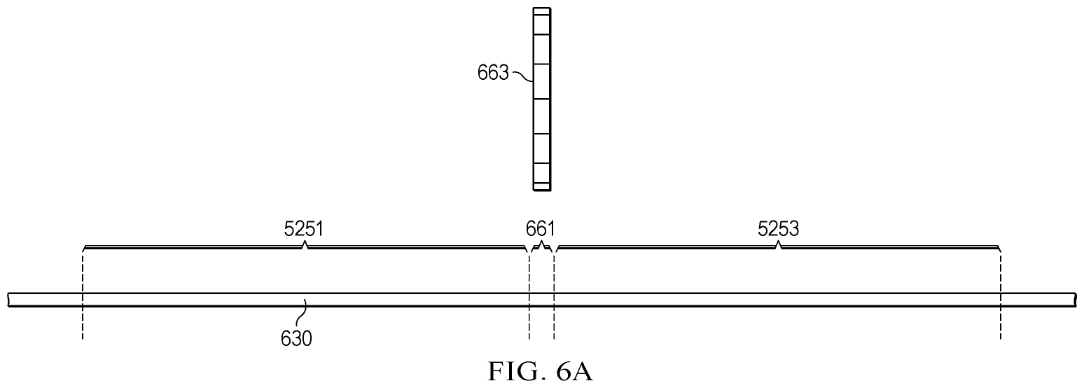

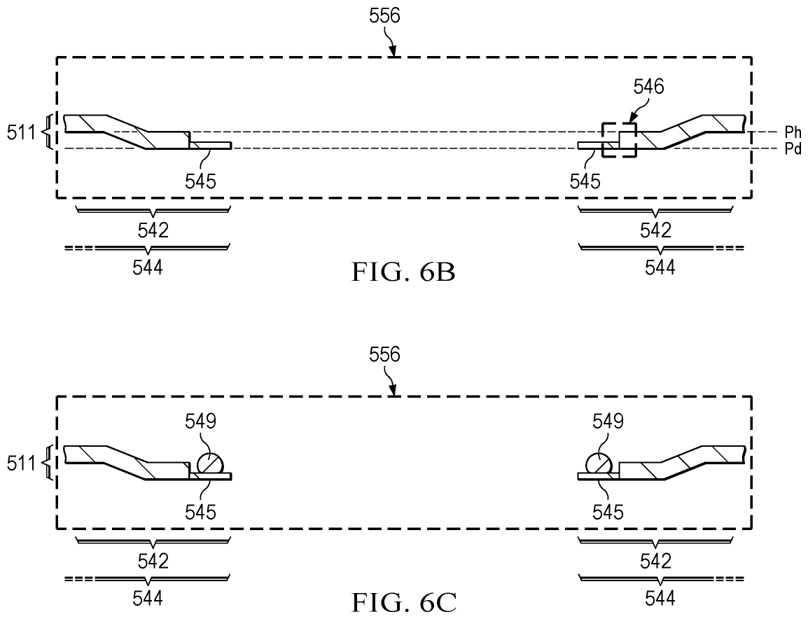

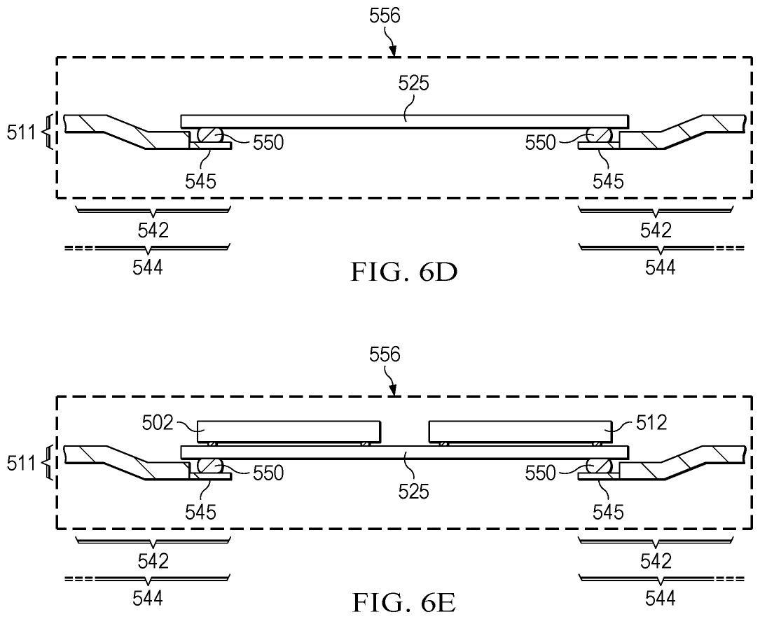

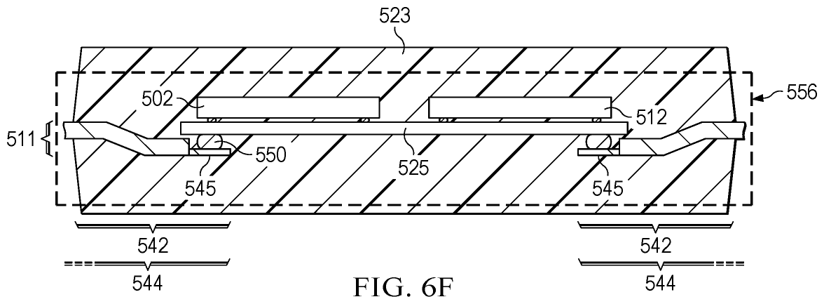

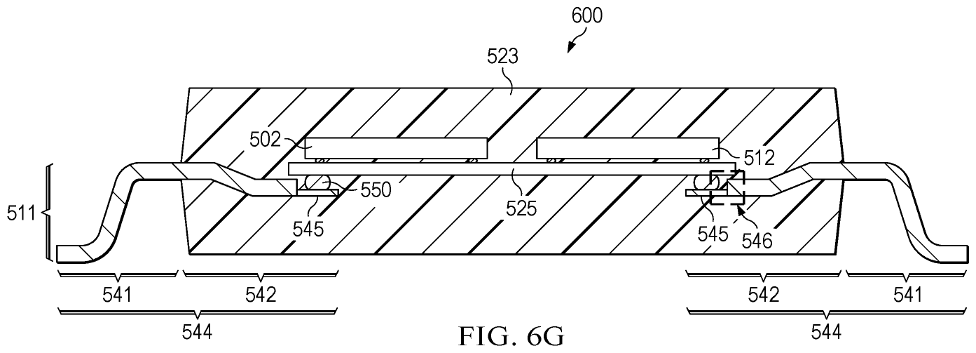

FIGS. 6A-6G illustrate, in a series of cross-sectional views, selected steps for forming a microelectronic device package of an arrangement.

In FIG. 6A, a sawing operation is shown separating individual multilayer package substrates 5251, 5253 from a panel or array of multilayer package substrates 630. The individual multilayer package substrates 5251, 5253 are spaced from one another by a saw street 661. A rotating saw blade 663 traverses the saw street 661 and is shown cutting the multilayer package substrate panel or array of multilayer package substrates 630.

In FIG. 6B, a leadframe 511 is shown in a cross-sectional view. The dashed line 556 indicates that the leads 544 are shown in part, in a finished microelectronic device package (see microelectronic device package 600 in FIG. 6G) the leads will have exterior portions forming terminals for the package, which are not shown in FIG. 6B. The leadframe 511 shown in FIG. 6B has downset leads. In a downset leadframe, the leads enter the package body at a middle portion of the sides in a horizontal plane (see plane Ph in FIG. 6B), and as the leads extend into the mold compound of the package, the leads are angled towards a board side surface of the packaged device to lie in a downset plane (see downset plane Pd in FIG. 6B). By using a downset leadframe, additional vertical space is made available for the multilayer package substrate and the flip chip mounted semiconductor dies, that lie on one side of the leads, so that the overall package thickness can remain relatively small and the components can fit in a standard thickness package. (If, in an alternative arrangement, a leadframe without the downset is used, the overall package thickness would need to be increased to accommodate all the elements mounted on one side of the leads within the package.) The interior portion 542 of the leads 544 extend to a lead pad 545 at the interior end. The leadframe 511 is a partially etched leadframe, with the leads having a full thickness, and the lead pads 545 having a partially etched thickness that is less than the full thickness of the leadframe 511, for example a half thickness. The difference in the thickness of the lead pad and the leads advantageously results in a step shown in dashed area 546, which is a crack stop feature of the arrangements. The leadframe 511, shown in FIG. 6B, and the multilayer package substrates 5251, 5253, shown in FIG. 6A, can be manufactured at different times, at different places, and by different vendors independent from one another so long as the multilayer package substrates are arranged to be mounted on the leadframes as described below.

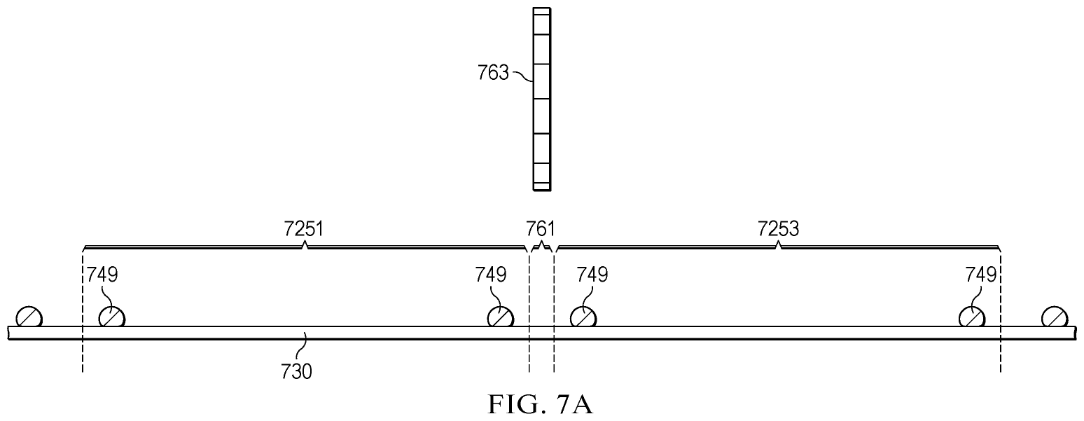

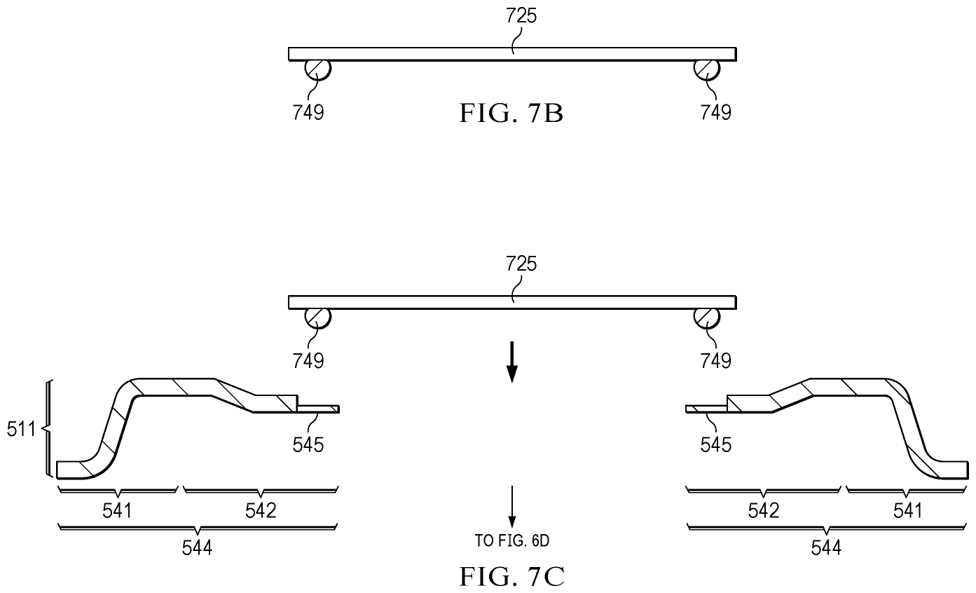

In FIG. 6C, the elements of FIG. 6B are shown after an additional processing step. In FIG. 6C, the leadframe 511 is shown with solder balls 549 positioned on the lead pads 545. The interior portion 542 of the leads 544 are shown extending to the lead pads 545. Again, dashed line 556 indicates this is a partial view, the leads 544 will extend beyond dashed line 556. (Note that an alternative approach where the solder balls are formed on the multilayer package substrate is shown in FIGS. 7A-7C and described below).

The solder balls 549 can be deposited in a couple of alternative processes. In one approach, a drop on demand solder dispensing process drops the solder balls 549 on the lead pads 545. In this approach, a solder dispenser traverses over the unit leadframes, which may be provided in an array or grid of unit leadframes that are temporarily tied together for gang processing. The solder balls 549 can be dropped and precisely positioned on the lead pads 545. In an alternative approach that is useful with the arrangements, a stencil process can be used. In a stencil process with a downset leadframe, the stencil is positioned on the downset portions of the leadframe, requiring the stencil be set within the leadframe downset area which can increase costs over a conventional stencil process. In an additional alternative arrangement, a conductive die attach epoxy can be dispensed to electrically and mechanically couple the lead pads to the multilayer package substrate with a conductive epoxy. A drop on demand process can be used to dispense the conductive die attach epoxy on the lead pads instead of solder balls 549.

Conductive die attach epoxy can include silver as a conductor, for example, and can be referred to as “silver sinter” or “silver filled” die attach epoxy. Conductive die attach epoxy is commercially available from various vendors, including Henkel Adhesive Technologies, of Dusseldorf, Germany and Westlake, Ohio, USA. Silver sinter die attach pastes can also be used to attach the multilayer package substrate to the lead pads of the leadframe. Silver sinter is applied and then melted to form a sinter joint.

In FIG. 6D, the elements of FIG. 6C are shown after a multilayer package substrate 525, such as 5251 or 5253 shown in the sawing operation of FIG. 6A, is mounted on the leadframe 511. After the multilayer package substrate 525 is positioned, solder joints 550 are formed by performing a thermal reflow process to melt the solder balls (see solder balls 549 in FIG. 6C) to form solder joints 550. Lands (not shown) on the multilayer package substrate 525 are coupled to the lead pads 545 on the leads 544 by the solder joints. The solder joints 550 are formed on the partially etched thickness of the lead pads 545.

FIG. 6E illustrates, in another cross-sectional view, the elements of FIG. 6D are shown after additional processing. Semiconductor dies 502, 512 are shown flip chip mounted to a device side surface of the multilayer package substrate 525, which has a board side surface mounted to the lead pads 545 of the leads. While the illustrated example shown in FIG. 6E illustrates two semiconductor dies 502, 512 mounted to the multilayer package substrate 525, in alternative arrangements, one semiconductor die can be mounted, or more than two semiconductor dies can be mounted. In additional arrangements, passive components such as capacitors, resistors, inductors, and coils can be mounted to either side of the multilayer package substrate; in still further arrangements, the multilayer package substrate may have passive components formed within the conductor layers and dielectric layers of the multilayer package substrate, for example conductor layers can be patterned to form a planar coil, a capacitor, a resistor, or a transformer.

In FIG. 6F, the elements of FIG. 6E are shown after additional processing. The leadframe 511 is shown with leads 544 partially covered by mold compound 523; while the mold compound surrounds and covers the semiconductor dies 502, 512, the multilayer package substrate 525, and the solder joints 550 on the lead pads 545 of the leads 544. The dashed line 556 again indicates the leads 544 are only partially shown in this view. In an example process, a transfer mold tool is used to form the mold compound 523. Mold compound, which can be an epoxy resin that is solid at room temperature, or powdered mold compound, can be placed in a mold tool and heated to a liquid state. The liquid mold compound is forced under pressure into runners and fills molds where the leadframes 511 are positioned, so that the mold compound surrounds the elements, The mold compound 523 is allowed to cure and forms a solid package body. After the molding, the individual units can be separated from one another by cutting through saw lanes between the molded devices using a mechanical saw to singulate the packaged devices.

FIG. 6G illustrates microelectronic device package 600 and includes the elements of FIG. 6F after additional processing. In FIG. 6G, a completed microelectronic device package 600 is shown after a singulation, trim, form (“STF”) process separates the leads 544 from temporary tie bars (not shown) that support the leads during processing, and trims and forms the exterior portion 541 of leads 544 to form terminals for the microelectronic device package 600. In the illustrated example arrangement of FIG. 6G, the exterior portions 541 of leads 544 have “gull wing” shapes from a side view, with the leads 544 arranged for use in an SMT board assembly process for forming solder joints to the external ends of the leads.

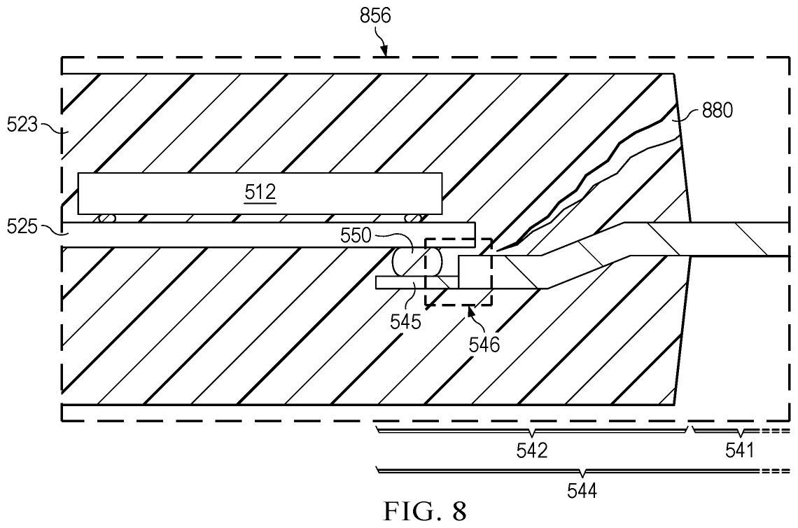

In the microelectronic device package 600, the solder joints 550 between the multilayer package substrate 525 and the leads 544 are placed on the partial thickness of the lead pads 545. A step is formed a shown in the dashed area 546 by the use of the arrangements with a partially etched leadframe forming a lead pad 545. By use of the arrangements, a crack stop feature is created by the step shape formed between the interior portion 542 of leads 544 and the lead pads 545, which protects the solder joints 550 from damage from a crack that might propagate through the mold compound 523 along the lead (see the example of a crack defect in FIG. 8, described below).

FIGS. 7A-7C illustrate, in another series of cross-sectional views, steps for forming an alternative arrangement for a microelectronic device package.

In FIG. 7A, a multilayer package substrate panel 730, which is similar to multilayer package substrate panel 630 in FIG. 6A, is shown with solder balls 749 deposited on a board side surface (note that the board side surface is oriented facing upwards in FIG. 7A, for convenience in illustration). Unit multilayer package substrates 7251 and 7253 are shown spaced from one another by the saw street 761, and a mechanical saw 763 is shown cutting through the multilayer package substrate panel 730 to separate the unit multilayer package substrates 7251, 7253 one from another.

In the example process of FIGS. 7A-7C, the multilayer package substrates have solder balls 749 applied before flip chip assembly to the leadframes. In an example process, the solder balls 749 are deposited in a stencil solder deposition process. After the solder balls 749 are stencil printed on the multilayer package substrate panel 730, a thermal reflow process is performed to permanently attach the solder balls 749 to the multilayer package substrate. In an alternative approach, a drop on demand solder deposition process can position the solder balls 749 on the multilayer package substrates, and a thermal reflow process is performed.

FIG. 7B illustrates a multilayer package substrate 725, such as 7251 or 7253 in FIG. 7A, is shown after being singulated from the multilayer package substrate panel 730 and now shown oriented board side down in preparation for mounting.

FIG. 7C illustrates the multilayer package substrate 725 being mounted on the lead pads 545 of leadframe 511, using a pick and place tool to mount the package substrate 725. After the mounting process of FIG. 7C, the packaging process continues as shown in FIG. 6D. The solder balls 549 are used to flip chip mount the multilayer package substrate 725 onto the lead pads 545 of the leadframe 511. In an example process, the solder balls will be subjected to a further thermal reflow to form solder joints to connect the multilayer package substrate 725 to the leadframe 511, the results of the process are shown in FIG. 6D.

After the multilayer package substrates are mounted to the leadframe using the solder joints as shown in FIG. 6D, the process continues to FIG. 6E, where semiconductor dies are mounted to the device side surface of the multilayer package substrates, to FIG. 6F, where mold compound is applied to the elements, and to FIG. 6G where the leads are trimmed and formed to complete the microelectronic device packages. Either the approach of FIGS. 7A-7C, where solder balls are mounted to the multilayer package substrate that is then mounted on the lead pads, or of FIGS. 6A-6C, where solder balls are mounted on the lead pads and then the multilayer package substrates are mounted to the lead pads, can be used to form the arrangements.

FIG. 8 illustrates, in a partial, cross-sectional and close-up view, an example crack defect and the advantages of the use of the arrangements. In FIG. 8, the close-up view in the dashed line 856 that indicates the partial view of a microelectronic device package as shown in FIG. 6G. In FIG. 8, mold compound 523 is shown over a lead 544 of a leadframe 511, a multilayer package substrate 525, and a semiconductor die 512. Solder joint 550 is formed between the lead pad 545 of the leadframe 511 and the multilayer package substrate 525. The step feature formed by the leadframe leads is shown in the dashed area 546.

A crack defect 880 is shown extending from the interface between the lead 544 and the mold compound 523 into the mold compound, the crack defect 880 is shown propagating along the interior portion 542 of lead 544. The step in dashed area 546 that is formed between the interior portion 542 of lead 544 and the partially etched lead pad 545 in the arrangements tends to stop the crack defect 880 from continuing propagation, and stops the crack before the crack defect 880 affects or damages the solder joint 550. In mechanical stress simulations, the stress on the solder joint in packages formed using the arrangements is substantially reduced (when compared to simulations using microelectronic device packages formed without use of the arrangements). The arrangements can be used in a variety of leaded packages without changes to tooling, to materials or to assembly process steps, allowing for low cost in implementing the arrangements while increasing the reliability of the microelectronic device packages.

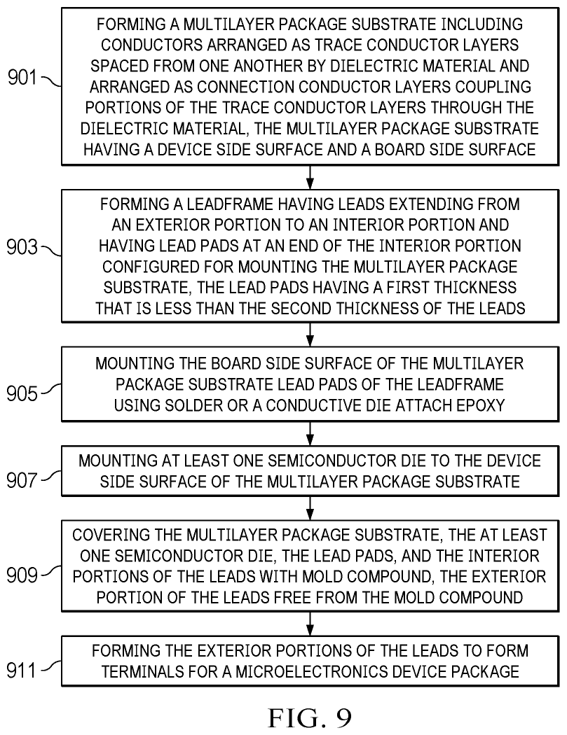

FIG. 9 illustrates, in a flow diagram, steps for forming a microelectronic device package of an arrangement. At step 901, the method begins by forming a multilayer package substrate with conductors arranged as trace conductor layers spaced from one another by dielectric material and arranged as connection conductor layers coupling portions of the trace conductor layers through the dielectric material, the multilayer package substrate having a device side surface and a board side surface. (See 325 in FIG. 3A, see the methods for forming a multilayer build-up package substrate in FIGS. 4A-4B, for example).

At step 903, the method continues by forming a leadframe having leads extending from an exterior portion to an interior portion and having lead pads at an end of the interior portion for mounting the multilayer package substrate, the lead pads having a first thickness that is less than a second thickness of the leads. (See leadframe 511 in FIG. 6B, with leads 544 having interior portion 542 and lead pads 545, see also leads 544 in FIG. 5C that have a first thickness T1 less than the second thickness T2 of the leads 544.) Note that the steps 901 and 903 are independent from one another, and the multilayer package substrate formation of step 901, and the leadframe formation of step 903 can be performed at different locations, by different entities, and at different times.

The method then continues at step 905, by mounting the board side surface of the multilayer package substrate lead pads of the leadframe using solder or a conductive die attach epoxy. (See, for example, FIG. 6D, where the multilayer package substrate 525 is mounted to leadframe 511 by solder joints 550 on lead pads 545, see also FIG. 7C where a multilayer package substrate 725 has solder balls 549 and is being mounted to leadframe 511 at lead pads 545, a solder reflow step will then form solder joints on the lead pads 545.)

The method continues to step 907, by mounting at least one semiconductor die to the device side surface of the multilayer package substrate. (See, for example, FIG. 6E, where semiconductor dies 502, 512 are shown mounted to the multilayer package substrate 525 on a device side surface.)

At step 909, the method continues by covering the multilayer package substrate, the at least one semiconductor die, the lead pads, and the interior portions of the leads with mold compound, the exterior portion of the leads free from the mold compound. (See, for example FIG. 6F, where the interior portion of the leads 544 of leadframe 511, the multilayer package substrate 525, the semiconductor dies 502 and 512 are covered by the mold compound 523).

At step 911, the method completes by forming the exterior portions of the leads to form terminals for a microelectronic device package. (See, for example, FIG. 6G where the exterior portions 541 of the leads 544 are gull wing shapes and form terminals for the microelectronic device package 600.) Use of the leadframe with the lead pads 545 of a thickness less than the leads 544 results in a step between the interior portion 542 of the leads and the lead pads 545, creating a crack stop feature that reduces or eliminates delamination and mold compound crack defects in the finished packages. (See, for example, FIG. 5C showing the step in dashed area 546, and see the complete microelectronic device package 600 in FIG. 6G with the step again shown in dashed area 546).

Modifications are possible in the described arrangements, and other alternative arrangements are possible within the scope of the claims.

What is claimed is:

1. A method of forming a microelectronic device package, comprising:
forming a multilayer package substrate comprising conductors arranged as trace conductor layers spaced from one another by a dielectric material and arranged as connection conductor layers coupling portions of the trace conductor layers through the dielectric material, the multilayer package substrate having a device side surface and a board side surface;
forming a leadframe having leads extending from an exterior portion to an interior portion and having lead pads at an end of the interior portion configured for mounting the multilayer package substrate, the lead pads having a first thickness that is less than a second thickness of the leads;
mounting the board side surface of the multilayer package substrate to the lead pads of the leadframe using solder joints or a conductive die attach epoxy;
mounting at least one semiconductor die to the device side surface of the multilayer package substrate;
covering the multilayer package substrate, the at least one semiconductor die, the lead pads, and the interior portions of the leads with mold compound, the exterior portion of the leads free from the mold compound; and
forming the exterior portions of the leads to form terminals for the microelectronic device package.

2. The method of forming a microelectronic device package of claim 1, wherein forming the multilayer package substrate further comprises:
patterning a first trace conductor layer over a carrier;
patterning a first connection conductor layer over the first trace conductor layer;
depositing the dielectric material over the first connection conductor layer and the first trace conductor layer;
grinding the dielectric material to expose the first connection conductor layer; and
patterning additional trace conductor layers, additional connection conductor layers, and depositing additional dielectric material over the additional trace conductor layers and over the additional connection conductor layers to form a multilayer build-up package substrate.

3. The method of forming a microelectronic device package of claim 2, wherein depositing the dielectric material over the first connection conductor layer further comprises depositing Ajinomoto build-up film.

4. The method of forming a microelectronic device package of claim 1, wherein forming the leadframe further comprises:
etching a sheet of leadframe material from opposite sides to form the leads of a full thickness of the sheet that is the second thickness and to form the partially etched lead pads having the first thickness that is less than the full thickness.

5. The method of forming a microelectronic device package of claim 4, wherein a step is formed between the interior ends of the leads and the lead pads.

6. The method of forming a microelectronic device package of claim 4, wherein the lead pads are positioned at a board side of the leads, so that the solder joints are formed on the lead pads at a level beneath a top side of the leads opposite the board side.

7. The method of forming a microelectronic device package of claim 4, wherein the lead pads are positioned at a top side of the leads, the leads having an opposite board side, so that the solder joints are formed on the lead pads at a level that matches the top side of the leads.

8. The method of forming a microelectronic device package of claim 1, wherein the multilayer package substrate is a molded interconnect substrate (MIS), a laminate, a flame-retardant glass reinforced (FR4) substrate, a bismaleimide-triazine (BT) resin substrate, or an Ajinomoto build-up film (ABF) build-up substrate.

9. The method of forming a microelectronic device package of claim 1, wherein the microelectronic device package is a small outline package with the leads on two sides extending from the mold compound.

10. The method of forming a microelectronic device package of claim 9, wherein the microelectronic device package is a small outline integrated circuit (SOIC) device package.

11. The method of forming a microelectronic device package of claim 1, wherein mounting the board side surface of the multilayer package substrate to the lead pads of the leadframe using solder or a conductive die attach epoxy further comprises:
prior to mounting the multilayer package substrate to the lead pads of the leadframe, dispensing solder balls on the lead pads of the leadframe.

12. The method of forming a microelectronic device package of claim 11, wherein dispensing solder balls on the lead pads of the leadframe further comprises using a drop on demand process, dropping solder balls onto the lead pads of the leadframe.

13. The method of forming a microelectronic device package of claim 11, wherein mounting the board side surface of the multilayer package substrate to the lead pads of the leadframe using solder or a conductive die attach epoxy further comprises:
prior to mounting the multilayer package substrate to the lead pads of the leadframe, dispensing a conductive die attach epoxy onto the lead pads of the leadframe.

14. The method of forming a microelectronic device package of claim 1, wherein mounting the board side surface of the multilayer package substrate to the lead pads of the leadframe using solder or a conductive die attach epoxy further comprises:
prior to mounting the multilayer package substrate to the lead pads of the leadframe, dispensing solder balls or a conductive die attach epoxy onto the board side surface of the multilayer package substrate; and
flip chip mounting the multilayer package substrate to the lead pads of the leadframe using the solder balls or the conductive die attach epoxy.

15. The method of forming a microelectronic device package of claim 1, wherein mounting at least one semiconductor die to the device side surface of the multilayer package substrate further comprises mounting a first semiconductor die and a second semiconductor die to the device side surface of the multilayer package substrate.

16. A method for forming a microelectronic device package, comprising:
forming a multilayer build-up package substrate comprising conductors arranged as trace conductor layers spaced from one another by dielectric material and arranged as connection conductor layers coupling portions of the trace conductor layers through the dielectric material, the dielectric material being Ajinomoto build-up film (ABF), the multilayer build-up package substrate having a device side surface and a board side surface;
using a partial etch process, forming a leadframe having leads extending from an exterior portion to an interior portion and having lead pads at an end of the interior portion configured for mounting the multilayer package substrate, the lead pads having a first thickness that is less than a second thickness of the leads, the second thickness being a full thickness of the leadframe;
mounting the board side surface of the multilayer build-up package substrate to the lead pads of the leadframe using solder;
mounting at least two semiconductor dies to the device side surface of the multilayer build-up package substrate;
covering the multilayer build-up package substrate, the at least two semiconductor dies, the lead pads, and the interior portions of the leads with mold compound, the exterior portion of the leads free from the mold compound; and
trimming and forming the exterior portions of the leads to separate the exterior portions of the leads and form terminals for the microelectronic device package.

17. The method for forming a microelectronic device package of claim 16, wherein mounting the board side surface of the multilayer build-up package substrate to the lead pads of the leadframe using solder further comprises:
prior to mounting the multilayer build-up package substrate to the lead pads of the leadframe, dispensing solder balls on the lead pads of the leadframe.

18. The method for forming a microelectronic device package of claim 17, wherein dispensing solder balls on the lead pads of the leadframe further comprises using a drop on demand process, dropping solder balls onto the lead pads of the leadframe.

19. The method for forming a microelectronic device package of claim 16, wherein a step is formed between the ends of the interior portion of the leads and the lead pads.

20. A microelectronic device package, comprising:
a leadframe having leads extending from an exterior portion to an interior portion and having lead pads at an end of the interior portion, the lead pads having a first thickness that is less than a second thickness of the leads;
a multilayer package substrate comprising conductors arranged as trace conductor layers spaced from one another by dielectric material and arranged as connection conductor layers coupling portions of the trace conductor layers through the dielectric material, the multilayer package substrate having a device side surface and a board side surface, the board side surface of the multilayer package substrate mounted to the leadframe by a solder joint on the lead pads;
at least two semiconductor dies mounted to the device side surface of the multilayer package substrate;
mold compound covering the multilayer package substrate, the at least two semiconductor dies, the lead pads, and the interior portions of the leads, the exterior portions of the leads free from the mold compound; and
the exterior portions of the leads forming terminals for the microelectronic device package.

21. The microelectronic device package of claim 20, the leadframe leads further comprising a step between the interior portion of the leads and the lead pads.

22. The microelectronic device package of claim 20, wherein the multilayer package substrate is a multilayer build-up package substrate and the dielectric material is Ajinomoto build-up film (ABF).
